(19) United States
(12) Patent Application Publication
(10) Pub. No.: US 2022/0071000 A1
(43) Pub. Date: Mar. 3, 2022

(54) CIRCUIT BOARD STRUCTURE AND MANUFACTURING METHOD THEREOF

(71) Applicant: Unimicron Technology Corp., Taoyuan City (TW)

(72) Inventors: Tzyy-Jang Tseng, Taoyuan City (TW); Shao-Chien Lee, Taipei City (TW); John Hon-Shing Lau, Taoyuan City (TW); Chen-Hua Cheng, Taoyuan City (TW); Ra-Min Tain, Hsinchu County (TW)

(73) Assignee: Unimicron Technology Corp., Taoyuan City (TW)

(21) Appl. No.: 17/149,664

(22) Filed: Jan. 14, 2021

Related U.S. Application Data
(60) Provisional application No. 63/071,369, filed on Aug. 28, 2020.

(30) Foreign Application Priority Data
Dec. 1, 2020 (TW) 109142148

(51) Int. Cl. H05K 1/02; H05K 1/11; H05K 3/40; H05K 3/02; H05K 3/00

(52) U.S. Cl. CPC H05K 1/0271; H05K 1/113; H05K 3/4069; H01L 33/62; H05K 3/0032; H05K 3/0047; H05K 3/02

(57) ABSTRACT

The disclosure provides a circuit board structure including at least two sub-circuit boards and at least one connector. Each of the sub-circuit boards includes a plurality of carrier units. The connector is connected between the sub-circuit boards, and a plurality of stress-relaxation gaps are defined between the sub-circuit boards.

### CROSS-REFERENCE TO RELATED APPLICATION

This application claims the priority benefit of U.S. provisional application Ser. No. 63/071,369, filed on Aug. 28, 2020 and Taiwan application serial no. 109142148, filed on Dec. 1, 2020. The entirety of each of the above-mentioned patent applications is hereby incorporated by reference herein and made a part of this specification.

### BACKGROUND

### Technical Field

The disclosure relates to a circuit board structure and a manufacturing method thereof, and particularly to a circuit board structure capable of avoiding warpage during reflow and a manufacturing method thereof.

### Description of Related Art

The picking and placing of light-emitting diodes (LEDs) are related to the flatness of the copper contact pads on the circuit board. If the copper contact pads on the circuit board are not well flat, the assembly yield is reduced, resulting in yield loss. The reflow temperature and the size of the circuit board also affect the assembly yield. When the reflow temperature is high, the circuit board having a larger size in area cannot be relieved due to the stress, and greater warpage ensues, thereby reducing the assembly yield of circuit boards. However, cutting a circuit board having a large size in area into individual pieces to avoid the warpage not only slows down the SMT assembly throughput, but also increases the process steps of assembling the LEDs to the display.

### SUMMARY

The disclosure provides a circuit board structure capable of avoiding and/or reducing warpage during reflow, improving the assembly yield of surface mount technology (SMT) components assembled thereon.

The disclosure also provides a manufacturing method of a circuit board structure adapted to manufacture the circuit board structure mentioned above.

The circuit board structure of the disclosure includes at least two sub-circuit boards and at least one connector. Each sub-circuit board includes multiple carrier units. The connector is connected between the sub-circuit boards, and multiple stress-relaxation gaps are defined between the sub-circuit boards.

In an embodiment of the disclosure, each of the aforementioned stress-relaxation gaps is a through hole.

In an embodiment of the disclosure, each of the carrier units mentioned above includes a core baseboard, multiple conductive glue blocks, a first circuit layer, and a second circuit layer. The core baseboard has an upper surface and a lower surface opposite to each other, and multiple through holes penetrating the core baseboard and connecting the upper surface and the lower surface. The conductive glue blocks are respectively disposed in the through holes of the core baseboard. The first circuit layer is disposed on the upper surface of the core baseboard and covers the upper surface and a top surface of each conductive glue block. The second circuit layer is disposed on the lower surface of the core baseboard and covers the lower surface and a bottom surface of each conductive glue block.

In an embodiment of the disclosure, each of the above-mentioned carrier units further includes a first solder mask and a second solder mask. The first solder mask is disposed on part of the upper surface of the first circuit layer and exposes part of the first circuit layer. The second solder mask is disposed on part of the lower surface of the second circuit layer and exposes part of the second circuit layer.

In an embodiment of the disclosure, each of the above-mentioned carrier units further includes a first surface treatment layer and a second surface treatment layer. The first surface treatment layer is configured on the first circuit layer exposed by the first solder mask. The second surface treatment layer is configured on the second circuit layer exposed by the second solder mask.

In an embodiment of the disclosure, at least one connector mentioned above includes multiple connectors, and the connectors are located on the same axis.

In an embodiment of the disclosure, at least one connector mentioned above includes multiple first connectors and multiple second connectors. The first connectors are located on a first axis, the second connectors are located on a second axis, and the first axis is perpendicular to the second axis.

The manufacturing method of the circuit board structure of the disclosure includes the following steps. A circuit substrate is provided, and multiple carrier units are formed on the circuit substrate. Multiple stress-relaxation gaps are formed on the circuit substrate, and the circuit substrate is divided into at least two sub-circuit boards and at least one connector. The connector is connected between the sub-circuit boards, and the sub-circuit board includes a carrier unit.

In an embodiment of the disclosure, forming the stress-relaxation gaps on the circuit substrate includes forming multiple through holes on the circuit substrate.

In an embodiment of the disclosure, the step of forming each carrier unit includes: a core baseboard is provided, the core baseboard having an upper surface and a lower surface opposite to each other, and multiple through holes penetrating the core baseboard and connecting the upper surface and the lower surface, wherein the core baseboard is in a B-stage condition. Multiple conductive glue blocks are filled in the through holes of the core baseboard, wherein the conductive glue blocks protrude from the upper surface and the lower surface. A first circuit layer and a second circuit layer are respectively formed on the core baseboard by pressing, curing, and patterning. The core baseboard is transformed from a B-stage condition to a C-stage condition. The first circuit layer is disposed on the upper surface of the core baseboard and covers the upper surface and a top surface of each conductive glue block, and the second circuit layer is disposed on the lower surface of the core baseboard and covers the lower surface and a bottom surface of each conductive glue block.

Based on the above, in the design of the circuit board structure of the disclosure, the connector connected between the sub-circuit boards defines the stress-relaxation gap with the sub-circuit boards, thereby releasing the stress generated by the circuit board structure during reflow. Therefore, the circuit board structure of the disclosure is capable of avoiding or reducing warpage, thereby improving the assembly yield of surface mount technology (SMT) components assembled thereon.

The accompanying drawings are included to provide a further understanding of the disclosure, and are incorporated in and constitute a part of this specification. The drawings illustrate embodiments of the disclosure and, together with the description, serve to explain the principles of the disclosure.

### BRIEF DESCRIPTION OF THE DRAWINGS

FIG. 1A is a schematic view of a circuit board structure according to an embodiment of the disclosure.

FIG. 1B is a schematic cross-sectional view of a carrier unit in FIG. 1A.

FIG. 2 is a schematic view of a circuit board structure according to another embodiment of the disclosure.

FIG. 3 is a schematic cross-sectional view of joining a circuit motherboard with the circuit board structure of FIG. 1A on which chips are disposed.

### DESCRIPTION OF THE EMBODIMENTS

Reference will now be made in detail to the present preferred embodiments of the disclosure, examples of which are illustrated in the accompanying drawings. Wherever possible, the same reference numbers are used in the drawings and the description to refer to the same or like parts.

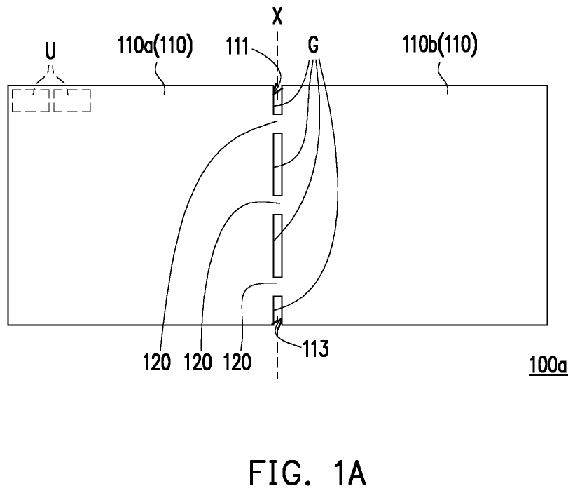

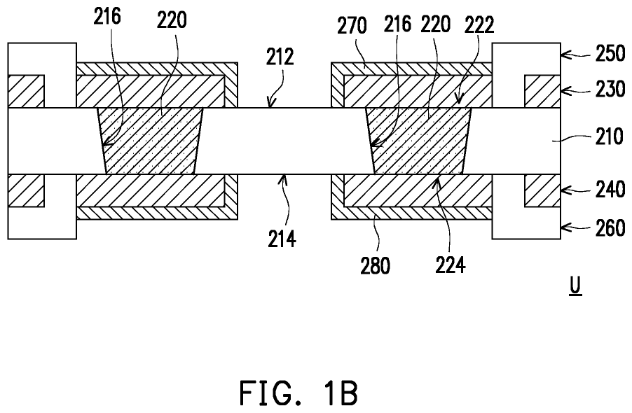

FIG. 1A is a schematic view of a circuit board structure according to an embodiment of the disclosure. FIG. 1B is a schematic cross-sectional view of a carrier unit in FIG. 1A. In

FIG. 1A, in this embodiment, a circuit board structure 100a includes at least two sub-circuit boards (two sub-circuit boards 110a and 110b are schematically shown) and at least one connector (three connectors 120 are schematically shown). Each of the sub-circuit board 110a and 110b includes a plurality of carrier units U. The connectors 120 are connected between the sub-circuit boards 110a and 110b, and a plurality of stress-relaxation gaps are defined between the sub-circuit boards 110a and 110b (four stress-relaxation gaps G are schematically shown). In other words, each of the connectors 120 is partially connected to two adjacent side walls 111 and 113 of the sub-circuit boards 110a and 110b, and there are stress-relaxation gaps G between the two side walls 111 and 113 and the connectors 120. The stress-relaxation gaps G and the connectors 120 are alternately disposed. Here, the connectors 120 are provided on the same axis X.

Furthermore, this embodiment first provides a circuit substrate 110 on which a plurality of carrier units U have been formed. After that, the stress-relaxation gaps G are formed on the circuit substrate 110, and the circuit substrate 110 is divided into the sub-circuit boards 110a and 110b and the connectors 120. Here, each of the stress-relaxation gaps G is embodied as a through hole, in which the stress-relaxation gaps G are formed by, for example, cutting or drilling, but the disclosure is not limited to this.

More specifically, in FIG. 1B, each of the carrier units U includes a core baseboard 210, a plurality of conductive glue blocks (two conductive glue blocks 220 are schematically shown), a first circuit layer 230, and a second circuit layer 240. The core baseboard 210 has an upper surface 212 and a lower surface 214 opposite to each other, and a plurality of through holes (two through holes 216 are schematically shown) that penetrate the core baseboard 210 and connect the upper surface 212 and the lower surface 214. The conductive glue blocks 220 are respectively disposed in the through holes 216 of the core baseboard 210. The first circuit layer 230 is disposed on the upper surface 212 of the core baseboard 210, and covers the upper surface 212 and a top surface 222 of each of the conductive glue blocks 220. The second circuit layer 240 is disposed on the lower surface 214 of the core baseboard 210, and covers the lower surface 214 and a bottom surface 224 of each of the conductive glue blocks 220. Here, the first circuit layer 230 and the second circuit layer 240 are each a patterned circuit layer, in which the first circuit layer 230 exposes part of the upper surface 212 of the core baseboard 210, and the second circuit layer 240 exposes part of the lower surface 214 of the core baseboard 210.

In the manufacturing process, the step of forming each carrier unit U includes: first a core baseboard 210 is provided, in which the core baseboard 210 is in a B-stage condition at this time, meaning that it has not been completely cured, and the thickness of the core baseboard 210 is, for example, 20 μm to 100 μm. Then, detachable films may be attached to the two opposite sides of the core baseboard 210, where the detachable film is made of polyester polymer (PET). Next, a drilling process is performed on the core baseboard 210 to form a through hole 216, where the drilling process is, for example, laser drilling or mechanical drilling, but the disclosure not limited thereto. Next, by printing or injection, a conductive glue is filled into the through hole 216 to form a conductive glue block 220. After that, the detachable films attached to the two opposite sides of the core baseboard 210 are removed, so that the top surface 222 and the bottom surface 224 of the conductive glue block 220 protrude respectively from the upper surface 212 and the bottom surface 214 of the core baseboard 210. Then, when the core baseboard 210 is in the B-stage condition, two copper foils are pressed on the upper surface 212 and the lower surface 214 of the core baseboard 210, where the copper foils covers the upper surface 212 and the lower surface 214 of the core baseboard 210 and the top surface 222 and the bottom surface 224 of the conductive glue block 220. Particularly, the surface roughness of the copper foil is less than 1 micron, wherein the surface roughness of the two opposite sides of the copper foils may be different from each other, and the copper foil faces the core baseboard 210 with the rougher surface. After that, a curing process is performed to fix the copper foils on the core baseboard 210. At this time, the core baseboard 210 transforms from the original B-stage condition to a C-stage condition, meaning that it is in a fully cured state. Next, a patterning process is performed on the two copper foils to form the first circuit layer 230 on the upper surface 212 of the core baseboard 210 and the second circuit layer 240 on the lower surface 214 of the core baseboard 210.

In FIG. 1B again, in this embodiment, each of the carrier units U further includes a first solder mask 250 and a second solder mask 260. The first solder mask 250 is disposed on part of the upper surface 212 of the first circuit layer 230 and exposes part of the first circuit layer 230. The second solder mask 260 is disposed on part of the lower surface 214 of the second circuit layer 240 and exposes part of the second circuit layer 240.

In addition, each of the carrier units U of this embodiment further includes a first surface treatment layer 270 and a second surface treatment layer 280. The first surface treatment layer 270 is disposed on the first circuit layer 230 exposed by the first solder mask 250, where the first surface treatment layer 270 covers the top surface and side surfaces of the first circuit layer 230 relatively far away from the core baseboard 210. The second surface treatment layer 280 is disposed on the second circuit layer 240 exposed by the second solder mask 260, where the second surface treatment layer 280 covers the top and side surfaces of the second circuit layer 240 relatively far away from the core baseboard 210. Here, the materials of the first surface treatment layer 270 and the second surface treatment layer 280 are, for example, electroless nickel electroless palladium immersion gold (ENEPIG), an organic solderability preservatives (OSP) layer, or electroless nickel immersion gold (ENIG), but the disclosure not limited thereto.

In sum, in the design of the circuit board structure 100a of this embodiment, the connectors 120 connected between the sub-circuit boards 110a and 110b define the stress-relaxation gaps G with the sub-circuit boards 110a and 110b, thereby releasing the stress generated by the circuit board structure 100a during reflow. Therefore, the circuit board structure 100a of the present embodiment is capable of avoiding or reducing warpage, thereby improving the assembly yield of surface mount technology (SMT) components assembled thereon.

It is to be noted that the following embodiments use the reference numerals and a part of the contents of the above embodiments, and the same reference numerals are used to denote the same or similar elements, and the description of the same technical contents is omitted. For the description of the omitted part, reference may be made to the above embodiments, and details are not described in the following embodiments.

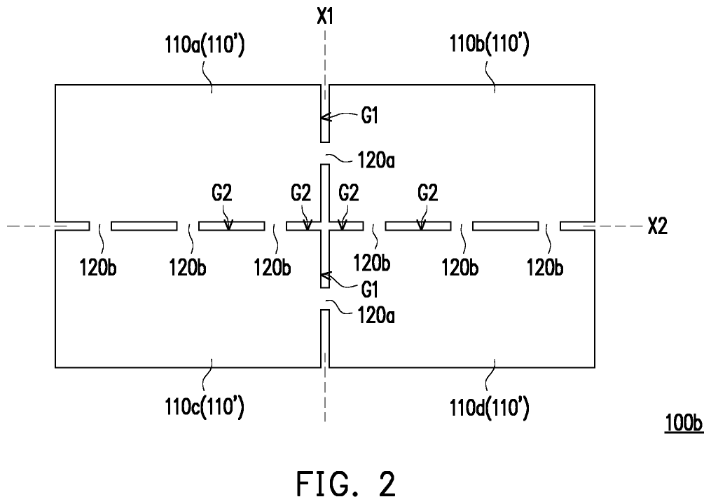

FIG. 2 is a schematic view of a circuit board structure according to another embodiment of the disclosure. Please refer to FIG. 2 and FIG. 1A at the same time. The circuit board structure 100b of this embodiment of FIG. 2 is similar to the circuit board structure 100a of FIG. 1A. The difference between the two is that: in this embodiment, stress-relaxation gaps G1 and G2 are formed on a circuit substrate 110′, and the circuit substrate 110′ is divided into sub-circuit boards 110a, 110b, 110c, and 110d, first connectors 120a, and second connectors 120b. Here, the first connectors 120a are provided on a first axis X1, the second connectors 120b are provided on a second axis X2, and the first axis X1 is perpendicular to the second axis X2.

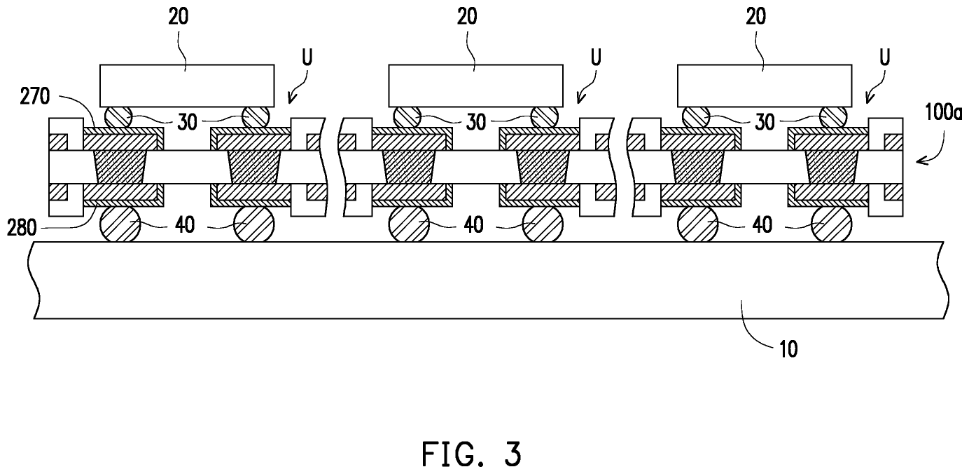

FIG. 3 is a schematic cross-sectional view of joining a circuit motherboard with the circuit board structure of FIG. 1A on which chips are disposed. In terms of application, in this embodiment of FIG. 3, a plurality of chips 20 may be electrically connected to the circuit board structure 100a through first bumps 30, where each chip 20 may be disposed to correspond to one of the carrier units U. The circuit board structure 100a may be electrically connected to a circuit motherboard 10 through second bumps 40, where the size of the second bump 40 is larger than the size of the first bump 30. This way, the range of applying the circuit board structure 100a can be expanded.

In sum in the design of the circuit board structure of the disclosure, the connector connected between the sub-circuit boards defines the stress-relaxation gap with the sub-circuit boards, thereby releasing the stress generated by the circuit board structure during reflow. Therefore, the circuit board structure of the disclosure is capable of avoiding or reducing warpage, thereby improving the assembly yield of surface mount technology (SMT) components assembled thereon.

Although the disclosure has been disclosed by the above embodiments, it will be apparent to one of ordinary skill in the art that modifications to the described embodiments may be made without departing from the spirit of the scope or spirit of the disclosure. In view of the foregoing, the scope of the disclosure will be defined by the attached claims and their equivalents and not by the above detailed descriptions.

What is claimed is:

1. A circuit board structure, comprising:
at least two sub-circuit boards, each of the at least two sub-circuit boards comprising a plurality of carrier units; and
at least one connector, connected between the at least two sub-circuit boards, wherein a plurality of stress-relaxation gaps are defined between the at least two sub-circuit boards.

2. The circuit board structure according to claim 1, wherein each of the stress-relaxation gaps is a through hole.

3. The circuit board structure according to claim 1, wherein each of the carrier units comprises:
a core baseboard, comprising an upper surface and a lower surface opposite to each other, and a plurality of through holes penetrating the core baseboard and connecting the upper surface and the lower surface;
a plurality of conductive glue blocks, disposed respectively in the through holes of the core baseboard;
a first circuit layer, disposed on the upper surface of the core baseboard, and adapted to cover the upper surface and a top surface of each of the conductive glue blocks; and
a second circuit layer, disposed on the lower surface of the core baseboard, and adapted to cover the lower surface and a bottom surface of each of the conductive glue blocks.

4. The circuit board structure according to claim 3, wherein each of the carrier units further comprises:
a first solder mask, disposed on part of the upper surface of the first circuit layer, and adapted to expose part of the first circuit layer; and
a second solder mask, disposed on part of the lower surface of the second circuit layer, and adapted to expose part of the second circuit layer.

5. The circuit board structure according to claim 4, wherein each of the carrier units further comprises:
a first surface treatment layer, disposed on the first circuit layer exposed by the first solder mask; and
a second surface treatment layer, disposed on the second circuit layer exposed by the second solder mask.

6. The circuit board structure according to claim 1, wherein the at least one connector comprises a plurality of connectors, and the connectors are located on the same axis.

7. The circuit board structure according to claim 1, wherein the at least one connector comprises a plurality of first connectors and a plurality of second connectors, the first connectors are located on a first axis, the second connectors are located on a second axis, and the first axis is perpendicular to the second axis.

8. A manufacturing method of a circuit board structure, comprising:
providing a circuit substrate, and forming a plurality of carrier units on the circuit substrate; and
forming a plurality of stress-relaxation gaps on the circuit substrate, dividing the circuit substrate into at least two sub-circuit boards and at least one connector, wherein the at least one connector is connected between the at least two sub-circuit boards, and the at least two sub-circuit boards comprise the carrier units.

9. The manufacturing method according to claim 8, wherein forming the stress-relaxation gaps on the circuit substrate comprises forming a plurality of through holes on the circuit substrate.

10. The manufacturing method according to claim 8, wherein forming each of the carrier units comprises:
providing a core baseboard, the core baseboard comprising an upper surface and a lower surface opposite to each other and a plurality of through holes penetrating the core baseboard and connecting the upper surface and the lower surface, wherein the core baseboard is in a B-stage condition;
filling a plurality of conductive glue blocks into the through holes of the core baseboard, wherein the conductive glue blocks protrude from the upper surface and the lower surface; and
forming respectively a first circuit layer and a second circuit layer on the core baseboard through pressing, curing, and patterning, wherein the core baseboard is transformed from the B-stage condition to a C-stage condition, the first circuit layer is disposed on the upper surface of the core baseboard and is adapted to cover the upper surface and a top surface of each of the conductive glue blocks, and the second circuit layer is disposed on the lower surface of the core baseboard and is adapted to cover the lower surface and a bottom surface of each of the conductive glue blocks.
